(19) United States
(12) Patent Application Publication
(10) Pub. No.: US 2008/0119025 A1
(43) Pub. Date: May 22, 2008

(54) Method of making a strained semiconductor device

(76) Inventors: O Sung Kwon, Wappingers Falls, NY (US); Oh Jung Kwon, Hopewell Junction, NY (US); Jin-Ping Han, Fishkill, NY (US); Henry Utomo, Newburgh, NY (US)

Correspondence Address: SLATER & MATSIL LLP, 17950 PRESTON ROAD, SUITE 1000, DALLAS, TX, 75252, US

(21) Appl. No.: 11/603,276

(22) Filed: Nov. 21, 2006

(51) Int. Cl. H01L 21/336; H01L 21/20

(52) U.S. Cl. 438/285; 438/483; 257/E21.103; 257/E21.403

(57) ABSTRACT

In a method of making a semiconductor device, a recess is formed in an upper surface of the semiconductor body of a first material. An embedded semiconductor region is formed in the recess. The embedded semiconductor region is formed from a second semiconductor material that is different than the first semiconductor material. An upper surface of the embedded semiconductor region is amorphized to create an amorphous region. A silicide is then formed over the amorphous region.

### TECHNICAL FIELD

This invention relates generally to semiconductor devices and methods, and more particularly to a strained semiconductor device and a method of making the same.

### BACKGROUND

Semiconductor devices are used in a large number of electronic devices, such as computers, cell phones and others. One of the goals of the semiconductor industry is to continue shrinking the size and increasing the speed of individual devices. Smaller devices can operate at higher speeds since the physical distance between components is smaller. In addition, higher conductivity materials, such as copper, are replacing lower conductivity materials, such as aluminum. One other challenge is to increase the mobility of semiconductor carriers such as electrons and holes.

One technique to improve transistor performance is to strain (i.e., distort) the semiconductor crystal lattice near the charge-carrier channel region. Transistors built on strained silicon, for example, have greater charge-carrier mobility than those fabricated using conventional substrates. One technique to strain silicon is to provide a layer of germanium (Ge) or silicon germanium (SiGe). A thin layer of silicon may be grown over the germanium-containing layer. Since the germanium crystal lattice is larger than silicon, the germanium-containing layer creates a lattice mismatch stress in adjacent layers. Strained channel transistors may then be formed in the strained silicon layer.

Another technique is to provide a stress layer over the transistor. Variants of stress layers can be used for mobility improvement and performance boost of devices. For example, stress can be provided by a contact etch stop layer (CESL), single layers, dual layers, stress memory transfer layers, STI liners, and CA liners. Most of these techniques use nitride layers to provide tensile and compressive stresses; however, other materials can be used in other applications, e.g., HDP oxide layers.

Another method for inducing strain, known as embedded silicon germanium involves creating a recess in the source and drain regions of a MOS transistor and growing a doped silicon germanium film within the recess in lieu of a conventional silicon source and drain region. The larger germanium crystal lattice creates a stress in the channel between the source and drain and thereby enhances the carrier mobility. Typically, the higher the Ge concentration in the Silicon germanium film grown within the recesses, the higher the carrier mobility that can be achieved.

### SUMMARY OF THE INVENTION

One embodiment of the present invention provides a method of making a semiconductor device. A recess is formed in an upper surface of the semiconductor body of a first material. An embedded semiconductor region is formed in the recess. The embedded semiconductor region is formed from a second semiconductor material that is different than the first semiconductor material. An upper surface of the embedded semiconductor region is amorphized to create an amorphous region. A silicide is then formed over the amorphous region.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-sectional view of a CMOS device;

FIGS. 2a-2f are cross-sectional views showing a method of making a device of the present invention;

FIG. 3 is a cross-section scanning electron microscope (SEM) after a silicide process;

FIG. 4 is a graph showing sheet resistance for experimental devices; and

FIG. 5 is a graph showing junction leakage current for experimental devices.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The invention will now be described with respect to preferred embodiments in a specific context, namely a method for improving carrier mobility in a CMOS device. Concepts of the invention can also be applied, however, to other electronic devices. As but one example, bipolar transistors (or BiCMOS) can utilize concepts of the present invention.

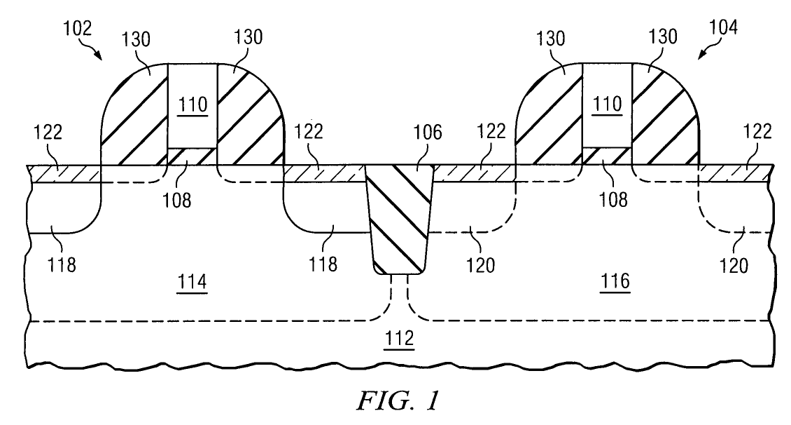

FIG. 1 illustrates a CMOS transistor pair that can utilize aspects of the present invention. The transistor pair includes a p-channel (PMOS) transistor 102 that is spaced from an n-channel transistor 104 by an isolation region 106. For each transistor 102, 104, a gate dielectric 108 and overlying gate electrode 110 are formed are formed over a semiconductor body 112. Spacers 130 are formed along sidewalls of the gate electrodes.

The p-channel transistor 102 is formed in an n-well 114 and the n-channel transistor 104 is formed in a p-well 116. The p-channel transistor 102 includes source/drain regions 118 formed from embedded silicon germanium that are formed to provide stress to the channel between the source drain regions 118 beneath the gate electrode 110. In this embodiment, the n-channel source/drain regions 120 are formed from n-doped silicon, which is the material of semiconductor 112. In other embodiments, the n-channel source/drain regions can be formed of a different material, such as embedded silicon carbon (eSiC). As also illustrated, both sets of source/drain regions 118 and 120 include lightly doped diffusion areas (LDD), which can minimize hot carrier effects by lowering the electric field in the vicinity of the drain.

To decrease the contact resistance of the source/drain regions, a silicide region 122 is formed over each region 118 and 120. In the preferred embodiment, the silicide region 122 is formed from nickel silicide. In other embodiments silicides from other materials such as cobalt, platinum, tantalum or titanium can be used. Nickel silicide is promising for salicide processes in for technologies below 65 nm due to the material's low sheet resistance (Rs) and lower thermal budget than cobalt silicide.

The embedded silicon germanium process used in the embodiment of FIG. 1 can help to enhance performance of the p-channel device by improving hole mobility. However, silicidation on embedded silicon germanium causes several issues that need to be solved. One issue is created by undesirable roughness at the interface between the silicide region 122 and embedded silicon germanium source/drain regions 118. Interface roughness caused by non-uniform silicide thickness on embedded silicon germanium is very susceptible to junction leakage current in source/drain (S/D) area and should be well controlled as the ground rule shrinks down.

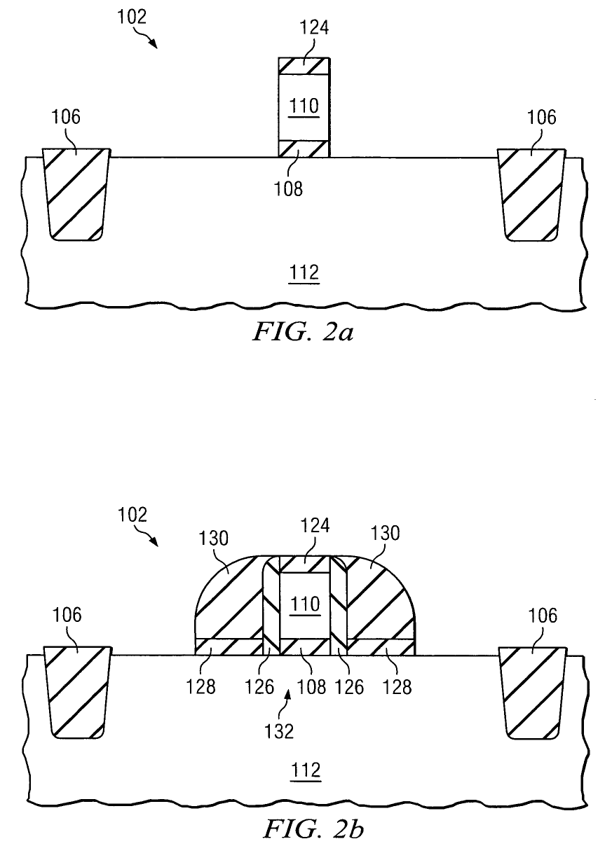

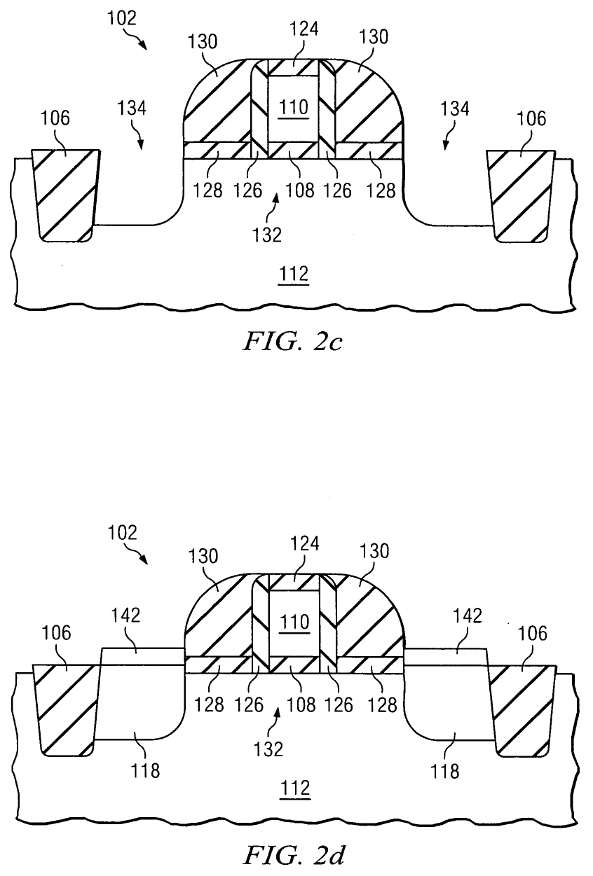

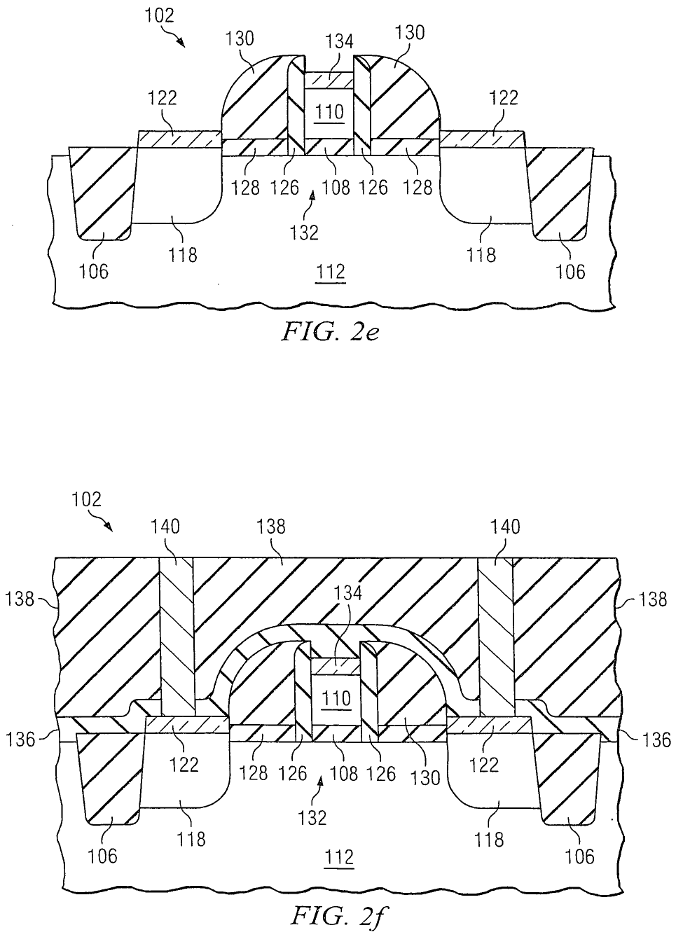

FIGS. 2a-2f provide an exemplary embodiment of a process flow that avoids some of the issues related to the formation of a transistor device with an embedded silicon germanium region. While certain details may be explained with respect to only one of the embodiments, it is understood that these details can also apply to other embodiments.

Referring first to FIG. 2a, a semiconductor body 112 is provided. In the preferred embodiment, the semiconductor body 112 is a silicon wafer. For example, the body 112 can be a bulk monocrystalline silicon substrate (or a layer grown thereon or otherwise formed therein) or a layer of a silicon-on-insulator (SOI) wafer. In other embodiments, other semiconductors such as silicon germanium, germanium, gallium arsenide or others can be used with the wafer. With these other materials, the grown source/drain regions (see FIG. 2d) would be other materials.

In the first embodiment, shallow trench isolation (STI) regions 106 are formed in the semiconductor body 112. First, isolation trenches can be formed using conventional techniques. For example, a hard mask layer (not shown here), such as silicon nitride, can be formed over the semiconductor body 112 and patterned to expose the isolation areas. The exposed portions of the semiconductor body 112 can then be etched to the appropriate depth.

The trenches are then filled with an isolating material. For example, exposed silicon surfaces can be thermally oxidized to form a thin oxide layer. The trenches can then be lined with a first material such as a nitride layer (e.g., Si₃N₄). The trenches can then be filled with a second material, such as an oxide. For example, a high plasma density (HDP) can be performed, with the resulting fill material being referred to as HDP oxide. In other embodiments, other trench filling processes can be used.

As also shown in FIG. 2a, a gate stack is formed. A gate dielectric 108 is deposited over exposed portions of the semiconductor body 112. In one embodiment, the gate dielectric 108 comprises an oxide (e.g., SiO₂), a nitride (e.g., Si₃N₄), or a combination of oxide and nitride (e.g., SiON, or an oxide-nitride-oxide sequence). In other embodiments, a high-k dielectric material having a dielectric constant of about 5.0 or greater is used as the gate dielectric 108. Suitable high-k materials include HfO₂, HfSiOₓ, Al₂O₃, ZrO₂, ZrSiOₓ, Ta₂O₅, La₂O₃, nitrides thereof, HfAlOₓ, HfAlOₓN_{1-x-y}, ZrAlOₓ, ZrAlOₓN_{y}, SiAlOₓ, SiAlOₓN_{1-x-y}, HfSiAlOₓ, HfSiAlOₓN_{y}, ZrSiAlOₓ, ZrSiAlOₓN_{y}, combinations thereof, or combinations thereof with SiO₂, as examples. Alternatively, the gate dielectric 108 can comprise other high-k insulating materials or other dielectric materials. As implied above, the gate dielectric 108 may comprise a single layer of material, or alternatively, the gate dielectric 108 may comprise two or more layers.

The gate dielectric 108 may be deposited by chemical vapor deposition (CVD), atomic layer deposition (ALD), metal organic chemical vapor deposition (MOCVD), physical vapor deposition (PVD), or jet vapor deposition (JVD), as examples. In other embodiments, the gate dielectric 108 may be deposited using other suitable deposition techniques. The gate dielectric 108 preferably comprises a thickness of about 10 Å to about 60 Å in one embodiment, although alternatively, the gate dielectric 108 may comprise other dimensions.

In the illustrated embodiment, the same dielectric layer would be used to form the gate dielectric 108 for both the p-channel and n-channel transistors. This feature is not required however. In alternate embodiments, the p-channel transistor and the n-channel transistor could each have different gate dielectrics.

The gate electrode 110 is formed over the gate dielectric 108. The gate electrode 110 preferably comprises a semiconductor material, such as polysilicon or amorphous silicon, although alternatively, other semiconductor materials may be used for the gate electrode 110. In other embodiments, the gate electrode 110 may comprise TiN, HfN, TaN, W, Al, Ru, RuTa, TaSiN, NiSiₓ, CoSiₓ, TiSiₓ, Ir, Y, Pt, Ti, PtTi, Pd, Re, Rh, borides, phosphides, or antimonides of Ti, Hf, Zr, TiAlN, Mo, MoN, ZrSiN, ZrN, HfN, HfSiN, WN, Ni, Pr, VN, TiW, a partially silicided gate material, a fully silicided gate material (FUSI), other metals, and/or combinations thereof, as examples. In one embodiment, the gate electrode 110 comprises a doped polysilicon layer underlying a silicide layer (e.g., titanium silicide, nickel silicide, tantalum silicide, cobalt silicide, or platinum silicide).

A hard mask layer 124 is formed over the gate electrode 110. This layer 124 can be used as a hard mask during the etching of gate electrode 110 and is preferably a nitride (e.g., Si₃N₄). The nitride will also prevent embedded silicon germanium material from forming on the gate electrode 110 during the later step of forming the silicon germanium source/drain stress-inducing regions (see FIG. 2a). The hard mask layer 124 is formed using conventional techniques. In other embodiments, the layer 124 can be formed from a material other than nitride.

The gate layer (and optionally the gate dielectric layer) are patterned and etched using known photolithography techniques to create the gate electrode 110 of the proper pattern. In a preferred embodiment of the present invention, the gate layer will be etched to achieve a gate length of less than 65 nm, for example, 45 nm. After formation of the gate electrodes 110, lightly doped source/drain regions (not shown) can be implanted using the gate electrode 110 as a mask. Other implants (e.g., pocket implants, halo implants or double-diffused regions) can also be performed as desired.

As shown in FIG. 2b, first spacers 126, which are formed from an insulating material such as an oxide and/or a nitride, can be formed on the sidewalls of the gate electrode 110. In the illustrated embodiment, first spacers 126 are formed by the deposition of a conformal layer followed by an anisotropic etch. Second spacers 130 are formed adjacent to the first spacers using conventional techniques. In a preferred embodiment, the first spacers 126 are formed from an oxide (e.g., a low temperature oxide) and the second spacers 130 are formed from a nitride. While illustrated with two spacers, the invention also contemplates structures with a single spacer, more than two spacers, or no spacers at all.

In the embodiment of FIG. 2b, the second spacers 130 are separated from the active area of semiconductor body 112 by a layer 128. The layer 128 can be a part of the gate oxide. More preferably, a low temperature oxide layer 128 is formed before the deposition of the nitride spacer 130. The layer 128 will protect the active area from the second spacer 130. These regions will also protect the extension regions (not shown) during source/drain formation. The regions 128 are optional.

Turning now to FIG. 2c, recesses 134 are formed in the source/drain areas of the transistor 102. Photoresist (not shown) is used to expose the semiconductor body 112 and the recesses 134 are formed by selective ion dry cutting and/or isotropic RIE. Alternatively, other forms of recess formation can be used such as wet or in-situ HCL etch or combinations thereof. The recesses extend to a depth of between about 10 nm and about 200 nm, in the preferred embodiment about 80 nm. The depth, however, is a function of the process used.

In the preferred embodiment, a CMOS structure is formed (as shown in FIG. 1). Since the strain is only desired for the p-channel transistors, resist (not shown) would fully cover any p-wells (where the n-channel transistors are formed). In the illustrated embodiment, the recesses 134 extend from the gate stack (e.g. spacer 130) to the STI region 106, but this feature is not needed. While it is desirable that the recesses 134 extend as close to channel 132 as possible, it is not necessary that the region extend to the STI region 106.

In FIG. 2d, the recesses are filled with embedded silicon germanium to form the embedded silicon germanium source/drain regions 118 using a selective epitaxial growth (SEG) technique. One goal of providing an embedded silicon germanium source/drain region 118 is to provide stress to the channel 132. The ratio of silicon to germanium throughout the source/drain regions 118 can be constant or they can be graded, as disclosed, for example, in co-pending application Ser. No. 11/473,883, which was filed on Jun. 23, 2006 and is incorporated herein by reference.

The present invention can be fabricated using any of a number of processes. As just one example, the recesses 134 in FIG. 2c are filled by exposing the semiconductor body 112 to SiH₂Cl₂ (dichlorosilane (DCS)) or SiH₄ (silane), HCl, B₂H₆, and GeH₄ (germane) gases under the following conditions:

| Parameter | Range |
|---|---|
| Temp | 500° C.–800° C. |
| Pressure | 5–50 torr |
| GeH₄ Flow Rate | 0–100 sccm |
| B₂H₆ Flow Rate | 0–100 sccm |
| DCS or SiH₄ Flow Rate | 50–300 sccm |
| HCl Flow Rate | 0–200 sccm |

The SiH₄ (silane) or SiH₂Cl₂ (DCS) gas serves as the silicon source gas and the GeH₄ (germane) serves as the germanium source gas in the deposition of the embedded silicon germanium source/drain regions 118. The B₂H₆ serves as a p-type dopant source, i.e., a source for boron dopants. In other embodiments, other gases may be used. If the source/drain regions, are subsequently doped, e.g., by implantation, the dopant source gas can be eliminated. Furthermore, in other embodiments where the embedded compound semiconductor is a material other than silicon germanium (e.g. silicon carbon) other gases may be used also. If the source/drain is not doped in situ, a subsequent implantation step can be performed.

The formation of the embedded silicon germanium source/drain regions 118 can conclude with the in-situ deposition of a silicon cap layer 142. After the embedded silicon germanium source/drain regions 118 are formed, an optional anneal step may be performed to activate the dopants in the source/drain regions 118. In this step, the semiconductor body 112 is heated to between about 900° C. and about 1400° C., as an example.

Referring now to FIG. 2e, silicide regions 122 are formed over the embedded silicon germanium source/drain regions 118. As noted above, one of the goals of the embodiments of the present invention is to improve the interface roughness between the embedded silicon germanium source/drain region 118 and the silicide region 122. One way to provide such improvement is to perform an amorphization step prior to the deposition of the siliciding metal.

The upper surface of the embedded silicon germanium region 118 is amorphized, preferably by ion implantation. In the preferred embodiment, germanium ions are implanted into the regions 118. For example, germanium ions can be implanted with a dose of about 10¹⁴ cm⁻² to about 10¹⁶ cm⁻² and an implantation energy between about 5 keV and about 20 keV. In other embodiments, other materials, such as xenon, carbon, or phosphorus can be implanted. The implantation step can be performed as a blanket implant (e.g., over the entire wafer) or only over the p-channel devices (e.g., after masking other portions of the wafer). The energy and dose of ion implantation might be dependent on the implantation material and semiconductor substrate and, therefore, may vary from the examples provided here.

As noted above, a silicon cap 142 can be deposited over the embedded silicon germanium region 118. The implantation step preferably occurs after the silicon cap 142 is deposited. The thickness of the silicon cap layer 142 can be adjusted based on the embedded silicon germanium and/or silicide process. For example, this cap layer 142 will typically have a thickness ranging between about 10 nm and about 20 nm.

Comparing FIG. 2e with FIG. 2d, it can be seen that, the layer 124 (or portions of layer 124) is removed from over the gate 110. For example, a nitride 124 can be removed by hot phosphoric acid etch, RIE or dry chemical etch. This step is preferably performed before the amorphizing implantation.

Silicide regions 122 are then formed over the embedded silicon germanium source/drain regions 118, and silicide region 134 is formed over the gate electrode 110 to form low resistivity upper surface regions. In preferred embodiments, a BHF pre-silicide cleaning step is first performed and followed by the deposition of a silicidation metal over the source and drain regions 118 and over the gate electrode 110. The structure is then subjected to an annealing process, e.g., a rapid thermal anneal. In the preferred embodiment, the silicidation metal is nickel, but the metal could also be cobalt, copper, molybdenum, titanium, tantalum, tungsten, erbium, zirconium, platinum, or combinations thereof. In one example, the semiconductor body 112 is then heated to about 300° C. to about 700° C. for about 2 seconds to 10 seconds to form a single layer of nickel silicide. The next step is to remove any unreacted metal by performing a strip step with aqua resia (AR), which is a mixture of HCl and HNO₃. To optimize silicide process, a second rapid thermal anneal step could follow the aqua resia strip step.

Referring now to FIG. 2f, a contact etch stop layer 136 (CESL) is formed over the surface of the device 102. In a preferred embodiment of the present invention, a nitride film (e.g., silicon nitride) is deposited, but other materials can be deposited. The contact etch stop layer 136 can be a stress-inducing layer, if desired. In one embodiment, the layer 136 exerts a first magnitude of strain on the p-channel transistors and a different magnitude of strain on the n-channel transistors.

An interlayer dielectric (ILD) layer 138 is then formed over the CESL 136. Suitable ILD layers include materials such as doped glass (BPSG, PSG, BSG), organo silicate glass (OSG), fluorinated silicate glass (FSG), spun-on-glass (SOG), silicon nitride, and PE plasma enhanced tetraethyloxysilane (TEOS), as examples.

In regions where contact holes are made, the ILD 138 is etched down to the CESL 136. Using a contact mask, photoresist (not shown) is deposited to mask off the non-exposed regions to the etch process. The ILD 138 is then etched down to the CESL 136 using standard etch techniques. In this step, the ILD 138 etches away at a faster rate than the CESL 136. Once the etch is complete, the photoresist may be removed. A second etch is then performed. This time, the CESL 136 is etched to expose the silicided source/drain regions 118 using the ILD 138 as a mask using standard etch techniques.

Source/drain contacts 140 are formed through the interlayer dielectric by depositing conductive material on the exposed portions of the silicided source/drain regions 118. Any standard contact fabrication technique may be used. Typically, a liner, such as Ti/TiN, is deposited to form an ohmic contact, after which tungsten is deposited using CVD techniques. Metallization layers that interconnect the various components are also included in the chip, but not illustrated for the purpose of simplicity.

In implementation of embedded silicon germanium, at least two schemes have been used. In a first one of these schemes, as described above, the embedded source/drain regions 118 are formed after the second spacer process. In another process, the embedded region are formed after the first spacer 126 but before the second spacer 130. The present invention works equally well with either or with other processes. The experimental results described below were performed with devices fabricated using the first scheme, but it is expected that similar results will be reached with other processes.

A study has been performed to determine any benefits of aspects to the present invention. In particular, effects of pre amorphization implantation (PAI) and in-situ silicon capping over embedded silicon germanium were examined to improve nickel silicide interface roughness. The results of this investigation will be discussion in the following paragraphs.

In one experiment, embedded silicon germanium was grown on a p-channel source/drain area by epitaxial growth of in-situ boron doped silicon germanium. For the experimental purpose, in-situ silicon of 20 nm thickness was grown on top of the embedded silicon germanium region. Before nickel deposition, a germanium per-amorphization implant was executed. The energy of this implantation was adjusted not to penetrate silicon capping layer. The nickel silicidation was completed by an appropriate annealing process and followed by contact and metallization processes. To check the physical interface roughness, a cross-sectional SEM was taken. For the electrical measurement, junction leakage current (J_{lkg}) and sheet resistance (Rs) were measured.

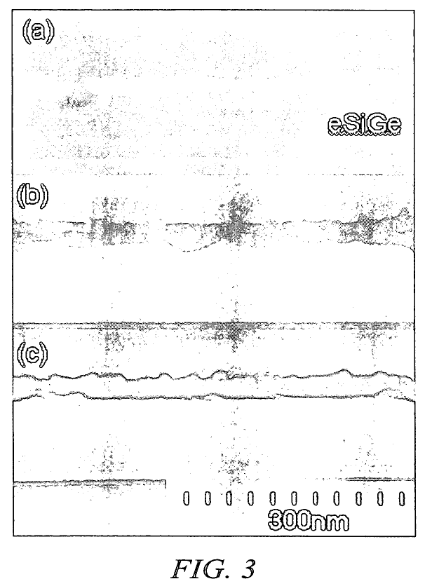

FIG. 3 provides cross-sectional SEM pictures showing the nickel silicon roughness on embedded silicon germanium. The top photograph, labeled (a) illustrates a case that did not include silicon capping or a germanium PAI. This baseline condition shows some voids were formed inside the silicide and that the interface between nickel silicon and embedded silicon germanium is very rough. It has been reported that in certain rapid thermal annealing (RTA) temperature range germano-silicide tends to be separated from nickel-germano-silicide to be stabilized thermodynamically and it makes void-like structure inside the silicide. See K. L. Pey, et al., J. Vac. Sci. Technol. B 22(2), pp. 852-858, 2004.

The middle SEM diagram, labeled (b), illustrates a case that included a silicon capping layer but without a germanium PAI. This condition does not show any void-like structure but it has non-uniform silicide thickness. It seems that 20 nm silicon layer on top of embedded silicon germanium is completely consumed in silicidation process. The measured silicide thickness, which is approximately 23 nm, is slightly thicker than the silicon capping layer thickness (20 nm). It appears that the in-situ silicon capping on embedded silicon germanium can effectively prevent the formation of germano-silicide but still shows rough interface. Increasing the thickness of silicon capping layer further is not desirable in many cases due to transistor performance degradation.

The bottom diagram, labeled (c), illustrates the case where both a silicon capping layer and a Ge PAI are performed. This condition shows no voids and a very uniform roughness. With Ge PAI just before Ni deposition, the silicon capping layer becomes amorphized silicon and its silicidation process makes more uniform than non-amorphized silicon layer.

FIG. 4 provides a graph that shows the dependency of Rs on experimental conditions. The sheet resistance was measured using a four-point probe method on STI bounded active area of about 300 nm width by about 2 um length. Even though severe formation of germano-silicide was improved with silicon capping layer in FIG. 3(b), there is no big change in Rs value and their variation. However, the condition with silicon capping combined with Ge PAI condition shows very tight Rs distribution, caused by improved uniform grain formation and the following smoothened interface roughness.

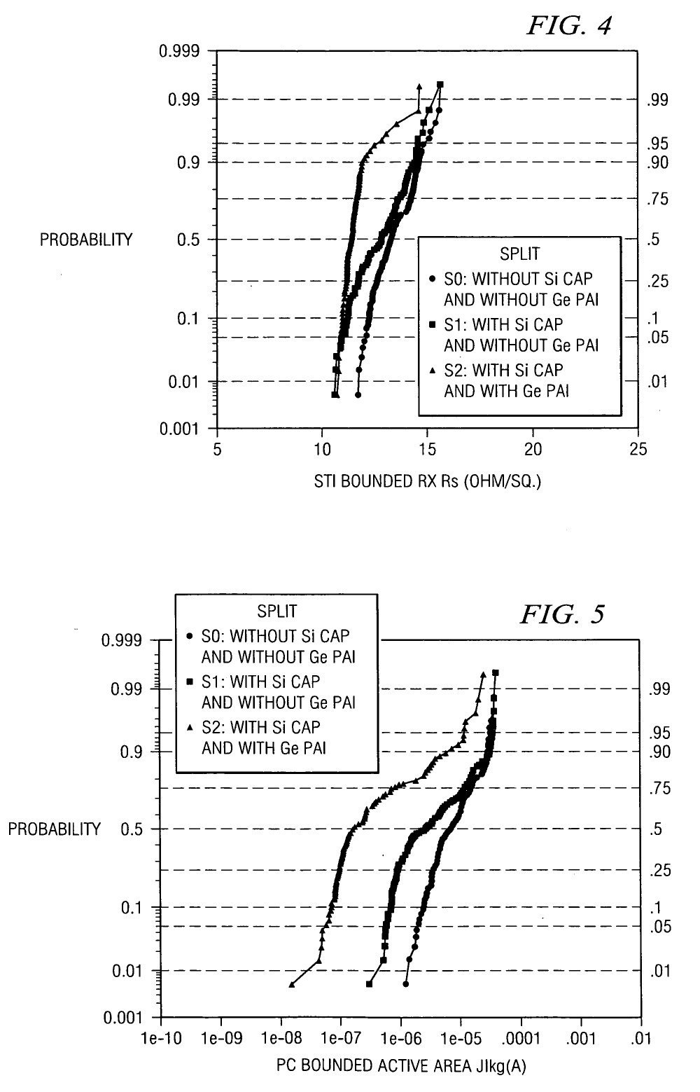

FIG. 5 shows leakage current (Jlkg) dependency on experiment conditions in PC bounded active area, which is composed of 1K array of about 520 nm by about 11.71 μm active area. Overall the far edge of the wafers show very leaky behavior compared to the wafer center due to process non-uniformity issues. It is clear, however, that silicon capping combined with Ge PAI improved the Jlkg compared to the other conditions. This result can possibly be explained by smoothened interface roughness.

Each of the embodiments described up to this point have been directed to a transistor device with an embedded silicon germanium region. It is understood, however, that the invention can be applied in other contexts. For example, the embedded source/drain regions described herein could be formed from a different material, such as silicon carbon. Further, the embedded regions could be part of devices other than field effect transistors.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of making a semiconductor device, the method comprising:
providing a semiconductor body including an upper surface, the semiconductor body comprising a first semiconductor material;
creating a recess in the upper surface of the semiconductor body;
forming an embedded semiconductor region in the recess, the embedded semiconductor region comprising a second semiconductor material that is different than the first semiconductor material;
amorphizing an upper surface of the embedded semiconductor region to create an amorphous region; and
forming a silicide over the amorphous region.

2. The method of claim 1, wherein the first semiconductor material comprises silicon and the second semiconductor material comprises silicon germanium.

3. The method of claim 2, further comprising forming a silicon cap layer over the embedded semiconductor region before amorphizing the upper surface.

4. The method of claim 3, wherein amorphizing the upper surface is performed to a depth such that the amorphous region is located entirely within the silicon cap layer.

5. The method of claim 2, wherein forming the embedded semiconductor region comprises epitaxially growing silicon germanium using SiH₄ as a silicon source gas and GeH₄ as a germanium source gas.

6. The method of claim 1, wherein forming the embedded semiconductor region comprises selectively growing silicon as the second semiconductor material in the recess.

7. The method of claim 1, wherein amorphizing the upper surface comprises performing an implantation step.

8. The method of claim 7, wherein amorphizing the upper surface comprises implanting germanium ions into the embedded semiconductor region.

9. The method of claim 7, wherein amorphizing the upper surface comprises implanting xenon ions into the embedded semiconductor region.

10. The method of claim 7, wherein amorphizing the upper surface comprises implanting carbon ions into the embedded semiconductor region.

11. The method of claim 1, wherein forming the embedded semiconductor region comprises in situ doping of the embedded semiconductor region.

12. The method of claim 1, wherein forming a silicide comprises depositing a metal layer over the embedded semiconductor region and heating the region to form the silicide.

13. The method of claim 12, wherein the metal layer comprises a nickel layer.

14. The method of claim 1, wherein the first semiconductor material is silicon and the second semiconductor material is silicon carbon.

15. A method of making a semiconductor device, the method comprising:
forming a recess in an upper surface of a silicon wafer;
growing an embedded silicon germanium region;
implanting a material to form an amorphous region over the silicon germanium region; and
forming a silicide over the amorphous region.

16. The method of claim 15, further comprising forming a silicon cap layer over the embedded silicon germanium region prior to implanting the material.

17. The method of claim 16, wherein the amorphous region is formed in the silicon cap layer.

18. The method of claim 16, wherein the amorphous region is formed entirely in the silicon cap layer.

19. The method of claim 15, wherein forming a silicide comprises depositing a metal layer over the embedded semiconductor region and heating the region to form the silicide.

20. The method of claim 19, wherein the metal layer comprises a nickel layer.

21. A method of making a semiconductor device, the method comprising:
providing a semiconductor body including an upper surface, the semiconductor body comprising a first semiconductor material;
forming a gate electrode overlying the upper surface of the semiconductor body and insulated therefrom;
forming spacers adjacent to sidewalls of the gate electrode;
creating first and second recesses in the upper surface of the semiconductor body, the first recess being spaced from the second recess by the gate electrode;
forming embedded semiconductor source/drain regions in the first and second recesses, the embedded semiconductor source/drain regions each comprising a second semiconductor material that is different than the first semiconductor material;
amorphizing an upper surface of the embedded semiconductor source/drain regions to create an amorphous region; and
forming a silicide over the amorphous region.

22. The method of claim 21, wherein forming embedded semiconductor source/drain regions comprises forming p-doped embedded semiconductor source/drain regions.

23. The method of claim 22, wherein the first material is silicon and the second material is silicon germanium.

24. The method of claim 23, further comprising forming a silicon cap layer over the embedded semiconductor source/drain regions prior to amorphizing the upper surface.

25. The method of claim 23, wherein forming a silicide comprises forming nickel silicide.

26. The method of claim 21, further comprising forming a stress-inducing layer over the upper surface after forming the silicide.

27. The method of claim 21, wherein making a semiconductor device comprises making a field effect transistor with a channel length that is less than 65 nm.
